(19) United States
(12) Patent Application Publication
(10) Pub. No.: US 2026/0047357 A1
(43) Pub. Date: Feb. 12, 2026

(54) METHOD FOR MANUFACTURING GAN HEMT POWER SEMICONDUCTOR EPITAXY WAFER WITH HIGH-QUALITY AND HIGH-RESISTANCE BUFFER REGION

(71) Applicant: WAVELORD CO., LTD., Gyeonggi-do (KR)

(72) Inventors: June O SONG, Gyeonggi-do (KR); Younghun Han, Gyeonggi-do (KR); Jihyung Moon, Gyeonggi-do (KR); Hyun Chul Lim, Gyeonggi-do (KR)

(21) Appl. No.: 19/291,897

(22) Filed: Aug. 6, 2025

(30) Foreign Application Priority Data
Aug. 8, 2024 (KR) 10-2024-0105874
Sep. 20, 2024 (KR) 10-2024-0127682

(51) Int. Cl. H01L 21/02; H10D 30/01; H10D 30/47; H10D 62/824

(52) U.S. Cl. CPC H01L 21/0257; H01L 21/0254; H01L 21/0262; H10D 30/015; H10D 30/475; H10D 62/824

(57) ABSTRACT

Embodiments according to the present invention provide a method for manufacturing a GaN HEMT power semiconductor epitaxy wafer having a high-quality, high-resistance buffer region, comprising: a first GaN buffer layer formation step in which carbon is doped using a metal-organic source among sources supplied for GaN growth as a precursor for carbon doping; and a second GaN buffer layer formation step in which carbon is doped by supplying a precursor for carbon doping separately from the sources supplied for GaN growth; wherein the precursor for carbon doping in the second GaN buffer layer formation step is at least one of CH₄ (methane), C₂H₄ (ethylene), C₂H₂ (acetylene), C₃H₈ (propane), i-C₄H₁₀ (iso-butane), and [N(CH₃)₃] (trimethylamine).

### CROSS-REFERENCE TO RELATED APPLICATIONS

This application claims the benefit and priority to Korean Patent Application Nos. 10-2024-0105874, filed Aug. 8, 2024 and 10-2024-0127682, filed on Sep. 20, 2024. The entire disclosures of the applications identified in this paragraph are incorporated herein by references.

### FIELD

The present disclosure relates to a method for manufacturing a GaN HEMT power semiconductor epitaxy wafer, and more particularly, to a method for manufacturing a GaN HEMT power semiconductor epitaxy wafer characterized by the formation of a high-quality, high-resistance buffer region.

### BACKGROUND

GaN HEMT power semiconductor epitaxial structures typically consist of a nucleation region, stress-relieving region, buffer region, channel region, and barrier region sequentially stacked on a growth substrate.

In an Al(1-y)Ga(y)N(barrier)/GaN(channel) heterojunction, a horizontal channel with a two-dimensional electron gas (2DEG) is formed at the interface of the GaN channel region, which has a small energy bandgap, without intentional doping. This is due to the polarization phenomenon of group III nitride semiconductors.

The polarization intensity is determined by the Al(1-y)Ga(y)N thickness and the Al composition(1-y), and the thickness is typically controlled by the Al composition(1-y).

In some cases, an AlN film less than 5 nm thick can be introduced prior to growing the Al(1-y)Ga(y)N barrier region over the GaN channel region.

In some cases, a capping region or a p-type group III nitride (GaN, AlGaN, AlInN, AlGaInN) film can be grown over the Al(1-y)Ga(y)N barrier region.

The buffer region serves as a current blocker, reducing vertical leakage current by imparting high-resistivity properties. This function is typically achieved by doping with carbon (C) or iron (Fe).

However, growing C- or Fe-doped GaN results in a deterioration in GaN crystal quality. Therefore, developing optimal growth conditions is a key challenge for the related technology field.

### SUMMARY

### Technical Problem

The present invention provides a method for improving the poor crystal quality of a high-resistance buffer region formed of C or Fe-doped GaN.

The present invention also provides a method for improving leakage current through the high-resistance buffer region.

The present invention also provides a method for improving the crystal quality and device reliability of a GaN HEMT active region, which comprises a GaN channel region and an AlGaN barrier region that are subsequently grown, by improving the crystal quality of the high-resistance buffer region.

### Technical Solution

Embodiments according to the present invention provide a method for manufacturing a GaN HEMT power semiconductor epitaxy wafer having a high-quality, high-resistance buffer region, comprising: a first GaN buffer layer formation step in which carbon is doped using a metal-organic source among sources supplied for GaN growth as a precursor for carbon doping; and a second GaN buffer layer formation step in which carbon is doped by supplying a precursor for carbon doping separately from the sources supplied for GaN growth; wherein the precursor for carbon doping in the second GaN buffer layer formation step is at least one of CH₄ (methane), C₂H₄ (ethylene), C₂H₂ (acetylene), C₃H₈ (propane), i-C₄H₁₀ (iso-butane), and [N(CH₃)₃] (trimethylamine).

In embodiments according to the present invention, the metal-organic source is a TMGa source, and carbon is doped by controlling the carbon concentration in the TMGa source by changing at least one of growth pressure, growth temperature, and V/III ratio as growth conditions for GaN growth.

In embodiments according to the present invention, the change in the growth conditions is performed by relatively lowering the growth pressure and/or the growth temperature to increase the carbon concentration.

In embodiments according to the present invention, the thickness of the first GaN buffer layer is formed thicker than the thickness of the second GaN buffer layer.

In embodiments according to the present invention, the second GaN buffer layer has a thickness of 50 to 99% of the thickness of the first GaN buffer layer.

In embodiments according to the present invention, the first and second GaN buffer layers constitute the buffer region, and the buffer region is formed by alternately stacking the first and second GaN buffer layers at least once.

Embodiments according to the present invention further comprises a step of forming an AlGaN buffer layer formed of Al(1-z)Ga(z)N (0.5≤z≤0.99).

In embodiments according to the present invention, the first and second GaN buffer layers and the AlGaN buffer layer constitute the buffer region, and the AlGaN buffer layer is provided as the uppermost layer of the buffer region or as an insertion layer between the first and second GaN buffer layers.

In embodiments according to the present invention, the AlGaN buffer layer is formed to a thickness of 5 to 500 nm.

### Advantageous Effects

According to the present invention, a high-resistance GaN buffer region can be secured by dividing the high-resistance GaN buffer region into two or more layers and using different carbon doping methods.

According to the present invention, by introducing a first GaN buffer layer (i-Carbon GaN layer) and a second GaN buffer layer (e-Carbon GaN layer) together, not only the high-resistance GaN buffer region but also the epitaxial crystal quality of the GaN HEMT active region, which consists of the channel and barrier regions that are subsequently grown, can be dramatically improved, as well as the leakage current of the GaN HEMT device.

According to the present invention, the first GaN buffer layer (i-Carbon GaN layer) prevents epitaxial crystal quality degradation occurring in the second GaN buffer layer (e-Carbon GaN layer), thereby securing a high-quality GaN buffer region.

According to the present invention, the doping concentration of the second GaN buffer layer (e-Carbon GaN layer) is relatively easy to control, which increases the electrical resistance of the buffer region and improves leakage current.

According to the present invention, the AlGaN buffer layer, which has a larger energy bandgap than the GaN buffer layer, can effectively block leakage current in the buffer region.

### BRIEF DESCRIPTION OF DRAWINGS

FIG. 1 is a cross-sectional view of a GaN HEMT power semiconductor epitaxy wafer according to one embodiment of the present invention.

FIG. 2 is a drawing illustrating the buffer region in FIG. 1 in detail.

FIGS. 3, 4 and 5 are diagrams illustrating growth conditions for the first GaN buffer region.

FIG. 6 is a drawing illustrating a modified example of the buffer region illustrated in FIG. 2.

FIG. 7 is a drawing illustrating another modified example of the buffer region illustrated in FIG. 2.

### DETAILED DESCRIPTION

Hereinafter, a method for manufacturing a GaN HEMT power semiconductor epitaxy wafer having a high-quality, high-resistance buffer region according to embodiments of the present invention will be described in detail with reference to the drawings.

The terms used below have been selected for convenience of explanation, and should be appropriately interpreted in a meaning that is consistent with the technical idea of the present invention without being limited to the dictionary meaning.

First, the structure of a GaN HEMT power semiconductor epitaxy wafer according to one embodiment of the present invention will be described.

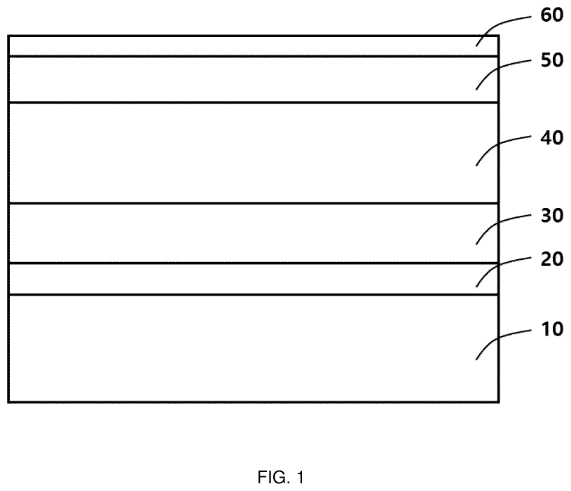

Referring to FIG. 1, a buffer region (40) is formed on a growth substrate (10), and a channel region (50) and a barrier region (60) are formed thereon as active regions.

Preferably, a nucleation region (20) and a stress-relieving region (30) are formed on the growth substrate (10) prior to the formation of the buffer region (40), but this is not necessarily required for the practice of the present invention.

The growth substrate (10) may be, for example, a silicon substrate, a silicon carbide (SiC) substrate, or an aluminum oxide substrate. The aluminum oxide substrate may be, for example, an Al₂O₃ substrate.

For silicon (Si) growth substrates, it is preferable to grow on the (111) plane, which has a high atomic packing ratio similar to the Group III nitride crystal structure (HCP), rather than on the (100) and (110) planes.

For silicon carbide (SiC) growth substrates, 4H—SiC growth substrates are preferred, as they have the same crystal structure as the Group III nitride crystal structure (HCP) and the smallest lattice constant difference. Growth on the Si-polar plane is preferred.

The nucleation region (20) promotes the growth of high-quality buffer regions (40), channel regions (50), and barrier regions (60). Furthermore, for Si growth substrates, it suppresses Melt Back Etching caused by the Si-Ga eutectic reaction. AlN thin film is preferred for the nucleation region (20).

When a GaN thin film or thick film is grown on a Si or SiC growth substrate and cooled to room temperature, tensile stress occurs within the GaN material layer due to thermo-mechanical stress, resulting in wafer warpage or cracking. A stress relief region (30) is introduced to suppress such wafer warpage or cracking.

The stress relief region (30) is composed of a multilayer structure of Al(1-x)Ga(x)N with different Ga composition ratios (x). Typically, it consists of two layers (double layer) or three layers (triple layer) with different Ga composition ratios. In some cases, the Ga composition ratio (x) is gradually increased toward the buffer region (40) to reach 100%. It can also be formed as an AlN/AlGaN superlattice structure.

The buffer region (40) has a high-resistive property, which reduces vertical leakage current and serves as a current blocking function.

The present invention aims to improve the crystal quality deterioration of C- or Fe-doped GaN using carbon (C) or iron (Fe) as a dopant, which is a common method for forming the buffer region (40).

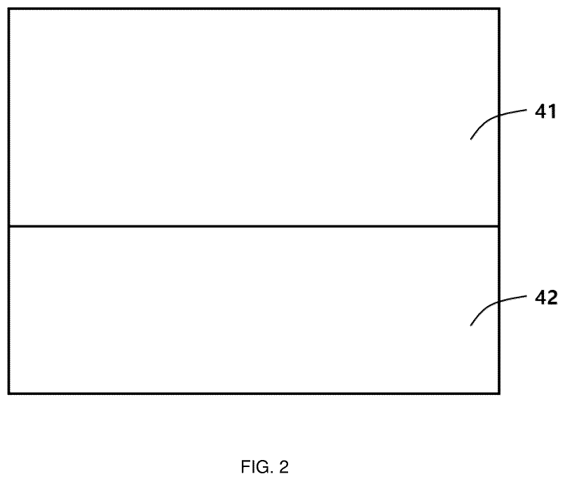

Referring to FIG. 2, the buffer region (40) is composed of C-doped GaN and comprises a first GaN buffer layer (41) and a second GaN buffer layer (42) with different carbon doping methods.

The first GaN buffer layer (41) and the second GaN buffer layer (42) are alternately stacked, and the stacking order is not limited.

The first GaN buffer layer (41) is introduced to prevent crystal quality deterioration of GaN and form a high-quality GaN buffer region (40).

The second GaN buffer layer (42) is introduced to control the doping concentration of the GaN buffer region (40) to increase the electrical resistance of the buffer region (40) and improve leakage current.

Accordingly, the first GaN buffer layer (41) functions to prevent epitaxy crystallinity degradation occurring in the second GaN buffer layer (42) and to secure a high-quality GaN buffer region (40).

The first GaN buffer layer (41) is formed using the metal-organic source material supplied to the MOCVD chamber for GaN growth as a precursor for carbon doping. In other words, no additional material is supplied for carbon doping.

Specifically, by changing the growth conditions for GaN growth, the carbon concentration in the TMGa source material supplied to the MOCVD chamber for GaN growth is adjusted, automatically supplying carbon dopant to the buffer region (40) for doping.

The first GaN buffer layer (41) can be defined as intrinsic carbon-doped GaN (‘i-Carbon GaN’) because it uses a metal-organic source material supplied for GaN growth to dope carbon.

The first GaN buffer layer (41) is grown by varying at least one of the growth pressure, growth temperature, and V/III ratio, which are the growth conditions for GaN growth. It is preferable to relatively lower the growth pressure and/or growth temperature to increase the carbon concentration in the TMGa source.

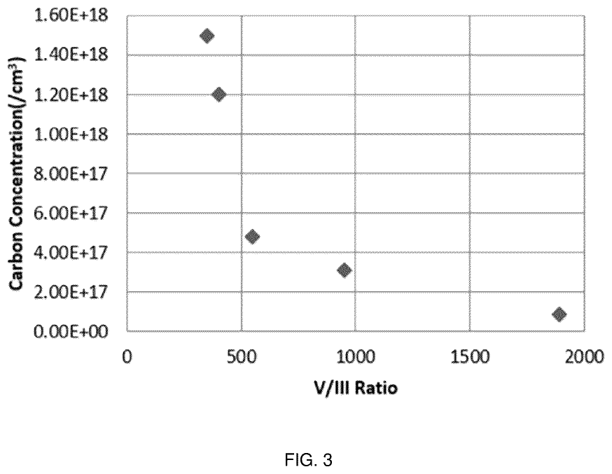

FIG. 3 shows the carbon concentration at different V/III ratios while maintaining the growth temperature and pressure. It can be seen that the carbon concentration is high at V/III ratios of 400 to 500, and that the carbon concentration decreases rapidly as the V/III ratio increases.

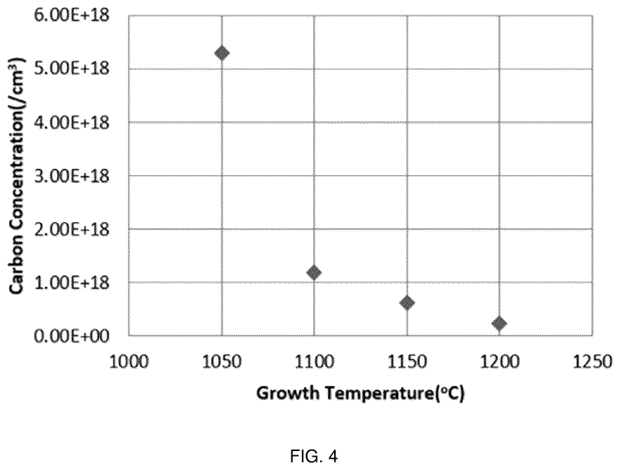

FIG. 4 shows the carbon concentration as a function of growth temperature while maintaining the growth pressure and V/III ratio. It can be seen that the carbon concentration is high at growth temperatures of 1050-1100° C., and then decreases sharply as the growth temperature increases.

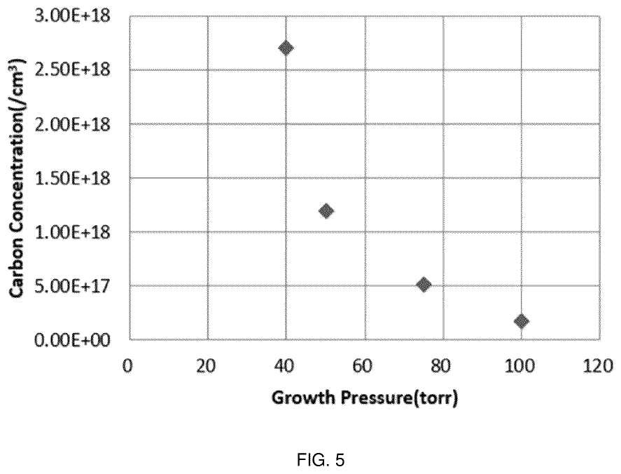

FIG. 5 shows the carbon concentration as a function of growth pressure while maintaining the growth temperature and V/III ratio. It can be seen that the carbon concentration is high at growth pressures of 40-50 torr, and then decreases sharply as the growth pressure increases.

FIGS. 3 to 5 suggest that reducing any one of the growth pressure, growth temperature, or V/III ratio compared to typical growth conditions can increase the carbon concentration. Furthermore, considering the units of carbon concentration in FIGS. 3 to 5, lowering the growth temperature and/or growth pressure leads to higher carbon concentrations than lowering the V/III ratio.

According to tests conducted by the inventors, it is preferable to form the first GaN buffer layer (41) by varying the growth conditions within the ranges of 950-1100° C., 50-100 torr, and 400-2000 V/III ratio.

Next, the second GaN buffer layer (42) is doped with carbon by supplying a precursor for carbon doping, in addition to the source supplied for GaN growth.

The second GaN buffer layer (42) can be defined as extrinsic carbon-doped GaN (‘e-Carbon GaN’, extrinsic carbon-doped GaN), as the precursor material for carbon doping is supplied externally separately.

The second GaN buffer layer (42) uses at least one of CH₄ (methane), C₂H₄ (ethylene), C₂H₂ (acetylene), C₃H₈ (propane), i-C₄H₁₀ (iso-butane), and [N(CH₃)₃] (trimethylamine) as a precursor material for carbon doping.

The second GaN buffer layer (42) allows for relatively easy control of the doping concentration, which increases the electrical resistance of the buffer region, thereby improving leakage current.

In this embodiment, the buffer region (40) is formed by sequentially stacking the first GaN buffer layer (41) and the second GaN buffer layer (42).

As previously explained, the first GaN buffer layer (41) prevents the crystallinity degradation of the epitaxy occurring in the second GaN buffer layer (42) and secures a high-quality GaN buffer region (40). Therefore, it is preferable that the first GaN buffer layer (41) be formed over the second GaN buffer layer (42). However, this is not limited to this configuration; the effects of the present invention can also be achieved by forming the second GaN buffer layer (42) over the first GaN buffer layer (41).

In this embodiment, the thickness of the first GaN buffer layer (41) is preferably greater than that of the second GaN buffer layer (42). This can also be attributed to the functionality of the first GaN buffer layer (41) in preventing the crystallinity degradation of the epitaxy occurring in the second GaN buffer layer (42).

Specifically, the thickness of the second GaN buffer layer (42) is preferably 50 to 99% of the thickness of the first GaN buffer layer (41).

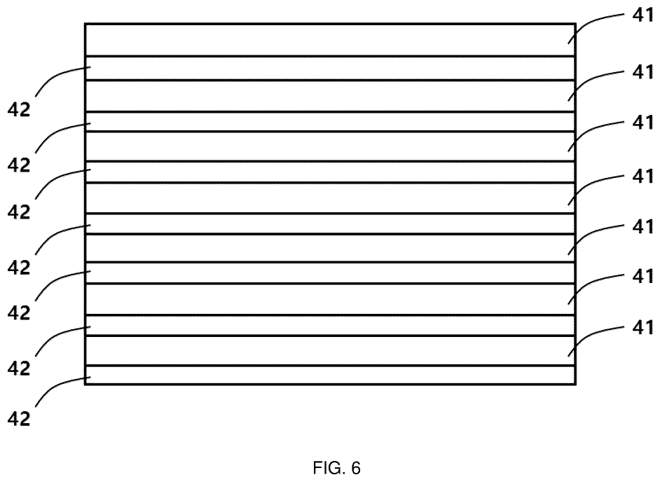

Next, referring to FIG. 6, in the present embodiment, the buffer region (40) is formed by alternately stacking multiple first GaN buffer layers (41) and second GaN buffer layers (42).

The buffer region (40) may include 10 to 300 pairs of first GaN buffer layers (41) and second GaN buffer layers (42).

The thickness of each of the first GaN buffer layers (41) and second GaN buffer layers (42) may be set within the range of 10 to 200 nm. This does not limit the first GaN buffer layers (41) (or second GaN buffer layers (42)) located at different locations to having the same thickness.

In addition, it is preferable that the total thickness of the buffer area (40) according to the present embodiment be formed to be 1 to 5 μm.

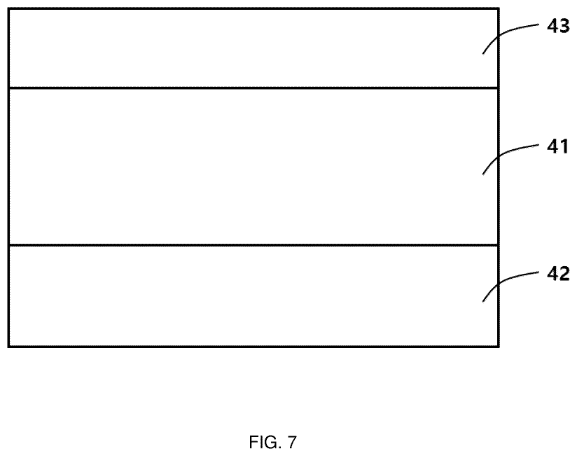

Next, referring to FIG. 7, in this embodiment, the buffer region (40) is not limited to the first GaN buffer layer (41) and the second GaN buffer layer (42), but an Al(1-z)Ga(z)N buffer layer (43) is added.

The Al(1-z)Ga(z)N buffer layer (43) has a larger energy bandgap than the GaN buffer layer, and is therefore introduced to more effectively block leakage current in the buffer region (40).

The Al(1-z)Ga(z)N buffer layer (43) is preferably formed with a thickness of 5 to 500 nm and has an Al composition ratio of 1 to 50% (i.e., 0.5≤z≤0.99).

The Al(1-z)Ga(z)N buffer layer (43) can be formed as part of the buffer region (40). However, as a specific example, it can be formed as shown in FIG. 7, and can also be formed on top of the first GaN buffer layer (41) and the second GaN buffer layer (42) that are alternately stacked multiple times, as shown in FIG. 6. Additionally, the Al(1-z)Ga(z)N buffer layer (43) can be provided as an intercalation layer between the first GaN buffer layer (41) and the second GaN buffer layer (42).

The embodiment of the present invention described above introduces the first and second GaN buffer layers with different carbon doping methods into the high-resistance GaN buffer region, thereby preventing the first GaN buffer layer from deteriorating the epitaxial crystallinity of the second GaN buffer layer and securing a high-quality GaN buffer region.

Furthermore, since the doping concentration of the second GaN buffer layer is relatively easy to control, this can be used to increase the electrical resistance of the buffer region, thereby improving leakage current.

As a result, the epitaxial crystal quality of the GaN HEMT active region, which consists of the high-resistance GaN buffer region as well as the subsequently grown channel and barrier regions, is significantly improved, as well as the leakage current of the GaN HEMT device.

Furthermore, embodiments of the present invention additionally introduce an AlGaN buffer layer with a larger energy bandgap than the GaN buffer layer, effectively blocking leakage current in the buffer region.

What is claimed is:

1. A method for manufacturing a GaN HEMT power semiconductor epitaxy wafer having a high-quality, high-resistance buffer region, comprising:
a first GaN buffer layer formation step in which carbon is doped using a metal-organic source among sources supplied for GaN growth as a precursor for carbon doping; and
a second GaN buffer layer formation step in which carbon is doped by supplying a precursor for carbon doping separately from the sources supplied for GaN growth;
wherein the precursor for carbon doping in the second GaN buffer layer formation step is at least one of CH₄ (methane), C₂H₄ (ethylene), C₂H₂ (acetylene), C₃H₈ (propane), i-C₄H₁₀ (iso-butane), and [N(CH₃)₃] (trimethylamine).

2. The method of claim 1, wherein the metal-organic source is a TMGa source, and carbon is doped by controlling the carbon concentration in the TMGa source by changing at least one of growth pressure, growth temperature, and V/III ratio as growth conditions for GaN growth.

3. The method of claim 2, wherein the change in the growth conditions is performed by relatively lowering the growth pressure and/or the growth temperature to increase the carbon concentration.

4. The method of claim 1, wherein the thickness of the first GaN buffer layer is formed thicker than the thickness of the second GaN buffer layer.

5. The method of claim 4, wherein the second GaN buffer layer has a thickness of 50 to 99% of the thickness of the first GaN buffer layer.

6. The method of claim 1, wherein the first and second GaN buffer layers constitute the buffer region, and the buffer region is formed by alternately stacking the first and second GaN buffer layers at least once.

7. The method of claim 1, further comprising: a step of forming an AlGaN buffer layer formed of Al(1-z)Ga(z)N (0.5≤z≤0.99).

8. The method of claim 7, wherein the first and second GaN buffer layers and the AlGaN buffer layer constitute the buffer region, and the AlGaN buffer layer is provided as the uppermost layer of the buffer region or as an insertion layer between the first and second GaN buffer layers.

9. The method of claim 7, wherein the AlGaN buffer layer is formed to a thickness of 5 to 500 nm.
